(19) United States
(12) Patent Application Publication
(10) Pub. No.: US 2018/0315725 A1
(43) Pub. Date: Nov. 1, 2018

(54) PACKAGE STRUCTURE HAVING BUMP WITH PROTECTIVE ANTI-OXIDATION COATING

(71) Applicant: NANYA TECHNOLOGY CORPORATION, New Taipei City (TW)

(72) Inventors: Po-Chun LIN, Changhua County (TW); Chin-Lung CHU, Taoyuan City (TW)

(21) Appl. No.: 15/497,227

(22) Filed: Apr. 26, 2017

(51) Int. Cl. H01L 23/00; H01L 23/31; H01L 21/56

(52) U.S. Cl. CPC H01L 24/13; H01L 24/05; H01L 23/3171; H01L 21/56; H01L 2224/13007; H01L 24/03; H01L 2224/13016; H01L 2224/13013; H01L 2224/13647; H01L 24/11

(57) ABSTRACT

A package structure includes a semiconductor substrate: a pad disposed on the semiconductor substrate; a conductive layer disposed on the pad; a protection coating; and a metal bump disposed on the conductive layer, and the metal bump covered with the protection coating so as to avoid oxidation of the metal bump.

### BACKGROUND

### Field of Invention

The present invention relates to a package structure and a manufacturing method thereof.

### Description of Related Art

Reflow soldering is a process in which a solder paste (a sticky mixture of powdered solder and flux) is used to temporarily attach one or several electrical components to their contact pads, after which the entire assembly is subjected to controlled heat, which melts the solder, permanently connecting the joint. Heating may be accomplished by passing the assembly through a reflow oven or under an infrared lamp or by soldering individual joints with a hot air pencil.

With the development of package structures, more and more processes of reflow are performed, and thus, the cost is increased. However, those skilled in the art sought vainly for a solution. For meeting requirements for decreasing the processes of reflow, advanced package forming methods and structures are needed.

### SUMMARY

An embodiment of the present disclosure is related to a package structure including a semiconductor substrate; a pad disposed on the semiconductor substrate; a conductive layer disposed on the pad; a protection coating; and a metal bump disposed on the conductive layer, and the metal bump covered with the protection coating so as to avoid oxidation of the metal bump.

Another embodiment of the present disclosure is related to a manufacturing method of a package structure. The manufacturing method includes providing a semiconductor substrate; forming a pad on the semiconductor substrate; forming a conductive layer on the pad; forming a metal bump on the conductive layer; forming a protection coating on the metal bump, so that the metal bump is covered with the protection coating to avoid oxidation of the metal bump.

Yet another embodiment of the present disclosure is related to a manufacturing method of package structure, the manufacturing method includes providing a semiconductor substrate; forming a pad on the semiconductor substrate; forming a passivation layer on the pad and the semiconductor substrate; forming an opening in the passivation layer for partially exposing a surface of the pad; forming a conductive layer being in contact with the surface of the pad and the passivation layer; forming a metal bump on the conductive layer; forming a protection coating on the metal bump; forming a layer of solder on the protection coating and directly over the metal bump; and performing a process of reflow to form a solder bump from the layer of solder and to remove the protection coating.

### BRIEF DESCRIPTION OF THE DRAWINGS

The invention can be more fully understood by reading the following detailed description of the embodiment, with reference made to the accompanying drawings as follows:

FIGS. 1 to 6 are cross-sectional views illustrating sequential processes for manufacturing a package structure according to some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

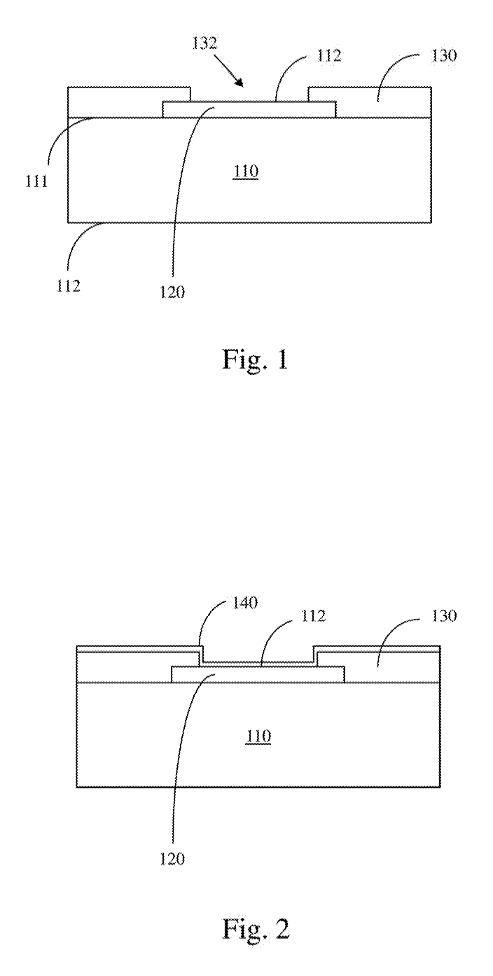

FIGS. 1 to 6 are cross-sectional views illustrating sequential processes for manufacturing a package structure according to some embodiments of the present disclosure, it is understood that additional operations can be provided before, during, and after the processes shown by FIGS. 1 to 6, and some of the operations described below can be replaced or skipped, for additional method embodiments. The order of the operations/processes may be interchangeable.

As shown in FIG. 1, a semiconductor substrate 110 is provided. The semiconductor substrate 110 has a first surface 111 and a second surface 112 opposing to each other. For example, the semiconductor substrate 110 is a silicon substrate or other suitable semiconductor substrate. The process starts with the first surface 111 of the semiconductor substrate 110, where a pad 120 is formed on the semiconductor substrate 110.

In structure, the pad 120 is disposed on the semiconductor substrate 110. The pad 120 is electrically connected to the semiconductor substrate 110. For example, the pad 120 is created in or on the surface of semiconductor substrate 110. The pad 120 serves as interface between the solder and electrical interconnects that are provided in the surface of the semiconductor substrate 110.

After the pad 120 e.g., a bonding pad or a contact pad) has been created on the surface of the semiconductor substrate 110, the pad 120 is passivated and electrically insulated by the deposition of a passivation layer 130 over the surface of the pad 120. After the passivation layer 130 is deposited and patterned, an opening 132 is formed in the passivation layer 130 and aligns with the pad 120.

In structure, the passivation layer 130 is disposed on the pad 120 and the semiconductor substrate 110. In other words, the pad 120 is disposed in the passivation layer 130, and the passivation layer 130 is recessed to form the opening 132 for partially exposing a surface 122 of the pad 120. In some embodiments, the passive layer 130 is formed SiO₂, such that the structure may have high forming accuracy and fine pitch capability. In various embodiments, the passivation layer 130 is formed from polyimide.

Referring to FIG. 2, a conductive layer 140 is formed on the pad 120 and the passivation layer 130, and the conductive layer 140 is electrically connected to the pad 120 In particular, the conductive layer 140 is in contact with the surface 122 of the pad 120 and the passivation layer 130. In some embodiments, the conductive layer 140 is a under metal bump metallurgy (UBM) layer. For example, the UBM layer (this layer may be a composite layer of metal such as chromium followed by copper followed by gold in order to promote improved adhesion (with the chromium) and to form a diffusion barrier layer or to prevent oxidation (the gold over the copper)) is formed over the passivation layer 130 and inside the opening 132 created in the passivation layer 130.

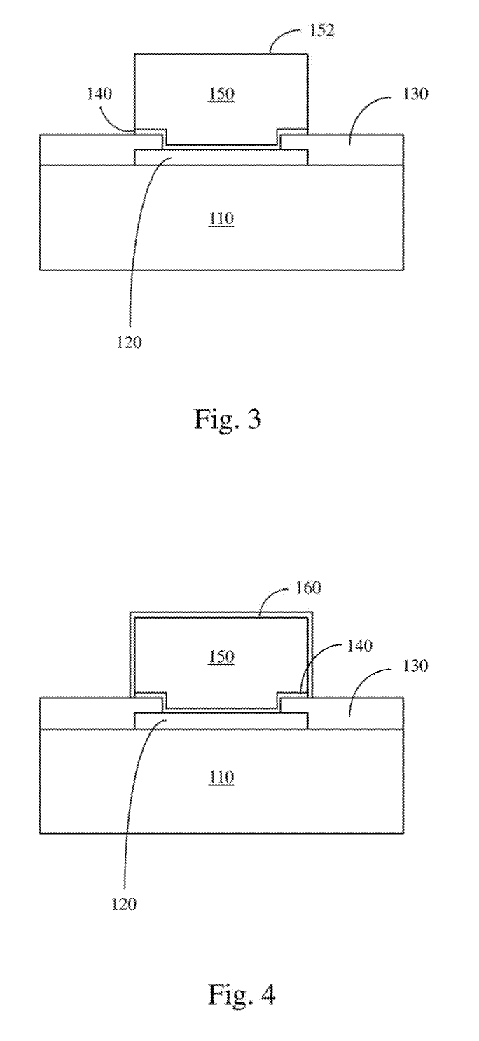

Referring to FIG. 3, a metal bump 150 is formed on the conductive layer 140, and a redundant portion of the conductive layer 140 is removed from the surface of the passivation layer 130. In FIG. 3, the metal bump 150 is disposed on the conductive layer 140, and the conductive layer 140 is electrically connected to the metal bump 150. In some embodiments, the metal bump 150 is formed from copper.

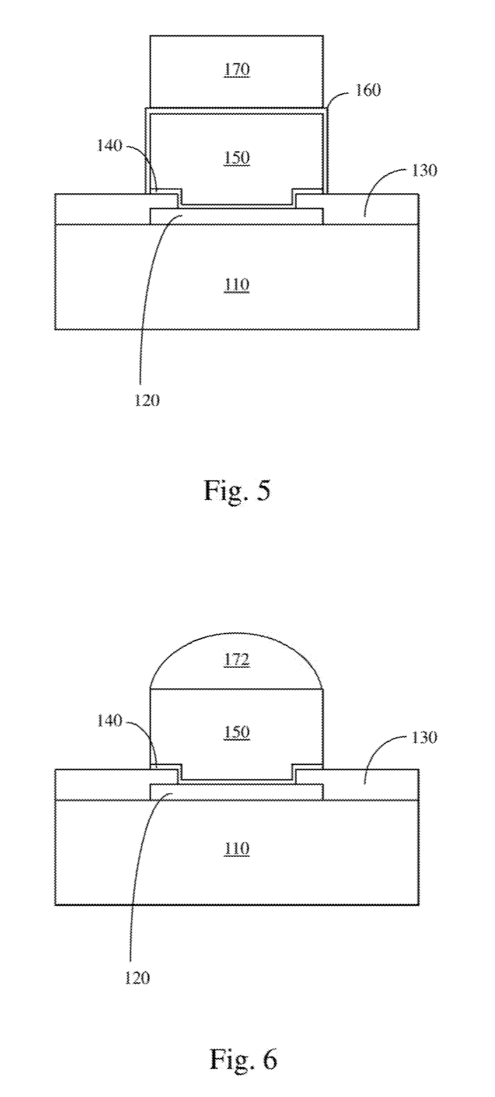

In structure, the metal bump has a non-rounding shape (e.g., a rectangle-like shape), and the metal bump 150 has a fiat surface 152 (e.g., a top surface) facing away from t he semiconductor substrate 110. In this way, the flat surface 152 of metal bump 150 can be utilized to carry a layer of solder 170, as shown in FIG. 5.

Referring to FIG. 4, a protection coating 160 is formed. In structure, the metal bump 150 is covered with the protection coating 160, so as to avoid oxidation of the metal bump 150. It should be noted that metal oxidation could, easily happen at the surface of metal bump 150 exposing to the air before seal if the protection coating 160 was omitted.

In some embodiments, the protection coating 160 is an organic solderability preservative (OSP) layer. The OSP layer has many advantages including low cost, smooth interface, high bonding strength, low contamination, and easy of fabrication.

Referring to FIG. 5, the layer of solder 170 is disposed on the protection coating 160, and the layer of solder 170 is positioned directly over the metal bump 150. In some embodiments, the layer of solder 170 is formed from tin.

In some approaches, the protection coating 160 is omitted, the layer of solder 170 is directly formed on the metal bump 150, and thus, an additional process of reflow (e.g., infrared reflow) is needed.

Compared with above approaches, in the present embodiments, the layer of solder 170 is formed on the protection coating 160 during which without needing the additional process of reflow (e.g., infrared reflow).

Referring to FIG. 6, a surface-mount technology (SMT) process is performed on the package structure after the layer of solder 170 has been formed. Then, the protection coating 160 is removed from the package structure. The solder bump 172 is formed from the layer of solder 170, and the solder bump 172 is in contact with the metal bump 150. In this way, the solder bump 172 is available to join with other object, such as a chip, a substrate, a carrier, and so on.

In the SMT process, process of reflow (e.g., SMT reflow) is performed to form the solder bump 172 from the layer of solder 170 as well as to remove the protection coating 160 simultaneously. In some embodiments, the protection coating 160 is the OSP layer. After the process of reflow, the OSP layer is evaporated. Moreover, the evaporation of the OSP layer can also clean the package structure.

It will be apparent to those skilled in the art that various modifications and variations can be made to the structure of the present invention without departing from the scope or spirit of the invention. In view of the foreging, it is, intended that the present invention cover modifications and variations of this invention provided they fall within the scope of the following claims.

1. A package structure, comprising:
a semiconductor substrate;
a pad disposed on the semiconductor substrate;
a conductive layer disposed on the pad;
a protection coating; and
a metal bump disposed on the conductive layer, wherein the metal bump is covered with the protection coating so as to avoid oxidation of the metal bump, and a portion of the protection coating is in direct contact with a top surface of the metal bump.

2. The package structure of claim 1, further comprising:
a passivation layer disposed on the semiconductor substrate,
wherein the pad is disposed in the passivation layer, the passivation layer has an opening for partially exposing a surface of the pad, and the conductive layer is in contact with the surface of the pad and the passivation layer.

3. The package structure of claim 1, wherein the metal bump has a flat surface facing away from the semiconductor substrate.

4. (canceled)

5. The package structure of claim 1, wherein the metal bump is formed from copper.

6. The package structure of claim 1, wherein the conductive layer is a under metal bump metallurgy (UBM) layer.

7. The package structure of claim 1, wherein the protection coating is an organic solderability preservative (OSP) layer.

8. The package structure of claim 1, further comprising:
a layer of solder disposed on the protection coating and positioned directly over the metal bump.

9. The package structure of claim 8, wherein the layer of solder is formed from tin.

10. The package structure of claim 1, wherein the passivation layer is formed from SiO2.

11-20. (canceled)
